(19) United States
(12) Patent Application Publication
(10) Pub. No.: US 2025/0174488 A1
(43) Pub. Date: May 29, 2025

(54) CHIP EJECTOR APPARATUS

(71) Applicant: Samsung Electronics Co., Ltd., Suwon-si (KR)

(72) Inventor: Sangjin Lee, Suwon-si (KR)

(21) Appl. No.: 18/958,018

(22) Filed: Nov. 25, 2024

(30) Foreign Application Priority Data
Nov. 29, 2023 (KR) 10-2023-0170034

(51) Int. Cl. H01L 21/687

(52) U.S. Cl. CPC H01L 21/68742; H01L 21/68778

(57) ABSTRACT

A chip ejector apparatus includes a holder located below a chip and defining a plurality of holes extending in a vertical direction, a pin support located below the holder, a support rod coupled to a lower surface of the pin support and configured to be driven in the vertical direction, a first vertical pin extending lengthwise in the vertical direction and disposed on the upper surface of the pin support, wherein the first vertical pin is inserted into a first hole of the plurality of holes, and wherein a lengthwise direction of the first vertical pin is parallel to the vertical direction, and a horizontal bar extending lengthwise in a first horizontal direction and coupled to an upper surface of the first vertical pin, wherein a lengthwise direction of the horizontal bar is parallel to the first horizontal direction.

### CROSS-REFERENCE TO RELATED APPLICATION

This application is based on and claims priority under 35 U.S.C. § 119 to Korean Patent Application No. 10-2023-0170034, filed on Nov. 29, 2023, in the Korean Intellectual Property Office, the disclosure of which is incorporated by reference herein in its entirety.

### BACKGROUND

The present disclosure relates to a chip ejector apparatus, and more particularly, to a chip ejector apparatus detaching a chip from a mount tape.

During a semiconductor packaging process, a dicing tape is attached to the rear surface of a wafer to prevent dies from falling off during a sawing process. The dies divided by the above sawing process may be separated from the dicing tape by a die ejector. Recently, as the dies have become thinner, there is an increasing risk that the dies are damaged while being separated from the dicing tape by the die ejector.

### SUMMARY

The provides a chip ejector apparatus that maintains a chip in a horizontal state without tilting or rotating when the chip is separated from a mount tape, thereby minimizing the occurrence of cracks.

Also, the objects of the present disclosure are not limited to the aforementioned object, but other objects not described herein will be clearly understood by those skilled in the art from the following description.

In order to achieve the above object, the present disclosure provides a chip ejector apparatus as follows.

According to an aspect of the present disclosure, a chip ejector apparatus includes a holder located below a chip and defining a plurality of holes extending in a vertical direction, a pin support located below the holder, wherein an upper surface of the pin support is adjacent to the holder, a support rod coupled to a lower surface of the pin support and configured to be driven in the vertical direction, a first vertical pin extending lengthwise in the vertical direction and disposed on the upper surface of the pin support, wherein the first vertical pin is inserted into a first hole of the plurality of holes, and wherein a lengthwise direction of the first vertical pin is parallel to the vertical direction, and a horizontal bar extending lengthwise in a first horizontal direction and coupled to an upper surface of the first vertical pin, wherein a lengthwise direction of the horizontal bar is parallel to the first horizontal direction.

According to an aspect of the present disclosure, a chip ejector apparatus includes a holder having a first body and a second body, wherein a plurality of holes extend from an upper surface of the second body to a lower surface of the second body in a vertical direction, and wherein a mount tape that is attached to a chip is disposed on an upper surface of the first body, a pin support located below the holder, a support rod coupled to a lower surface of the pin support and configured to be driven in the vertical direction, a plurality of vertical pins disposed on an upper surface of the pin support, wherein each vertical pin of the plurality of vertical pins extends lengthwise in the vertical direction and is inserted into a corresponding hole among the plurality of holes, and a horizontal bar extending lengthwise in a first horizontal direction and coupled to an upper surface of each vertical pin of the plurality of vertical pins. The upper surface of the first body is higher than the upper surface of the second body in the vertical direction relative to the upper surface of the pin support. The first horizontal direction is parallel to a lengthwise direction of the horizontal bar and the vertical direction is parallel to a lengthwise direction of each vertical pin of the plurality of vertical pins.

According to an aspect of the present disclosure, a chip ejector apparatus includes a holder having a first body and a second body, wherein the second body defines a plurality of holes, wherein the plurality of holes extend from an upper surface of the second body to a lower surface of the second body in a vertical direction, and wherein a mount tape that is attached to a chip is disposed on an upper surface of the first body, a pin support located below the holder, a support rod coupled to a lower surface of the pin support and configured to be driven in the vertical direction, a plurality of vertical pins disposed on an upper surface of the pin support, wherein each vertical pin of the plurality of vertical pins extends lengthwise in the vertical direction and is inserted into a corresponding hole among the plurality of holes, a pin coupling member located between the pin support and the plurality of vertical pins and configured to be detachably coupled to each vertical pin of the plurality of vertical pins, and a horizontal bar coupled to an upper surface of each vertical pin of the plurality of vertical pins and extending lengthwise in a first horizontal direction. A length of the horizontal bar in the first horizontal direction is substantially equal to or less than a length of the chip in the first horizontal direction. A height difference in the vertical direction corresponds to a shortest distance between the upper surface of the first body and the upper surface of the second body. A thickness of the horizontal bar in the vertical direction is substantially equal to the height difference between the upper surface of the first body and the upper surface of the second body in the vertical direction.

### BRIEF DESCRIPTION OF THE DRAWINGS

Embodiments will be more clearly understood from the following detailed description taken in conjunction with the accompanying drawings in which:

FIG. 1 is a cross-sectional view showing a chip ejector apparatus according to embodiments;

FIG. 2 is a plan view showing the chip ejector apparatus according to embodiments;

FIGS. 3 and 4 are cross-sectional views showing an operation of the chip ejector apparatus according to embodiments;

FIG. 5 is a cross-sectional view showing a chip ejector apparatus according to embodiments;

FIG. 6 is a plan view showing the chip ejector apparatus according to embodiments;

FIG. 7 is a cross-sectional view showing a chip ejector apparatus according to embodiments;

FIG. 8 is a plan view showing the chip ejector apparatus according to embodiments;

FIG. 9 is a cross-sectional view showing a chip ejector apparatus according to embodiments;

FIG. 10 is a plan view showing the chip ejector apparatus according to embodiments;

FIG. 11 is a cross-sectional view showing a chip ejector apparatus according to embodiments;

FIG. 12 is a plan view showing the chip ejector apparatus according to embodiments;

FIG. 13 is a cross-sectional view showing a chip ejector apparatus according to embodiments; and

FIG. 14 is a plan view showing the chip ejector apparatus according to embodiments.

### DETAILED DESCRIPTION OF THE EMBODIMENTS

Hereinafter, embodiments are described in detail with reference to the accompanying drawings. The same reference numerals are given to the same elements in the drawings, and repeated descriptions thereof are omitted.

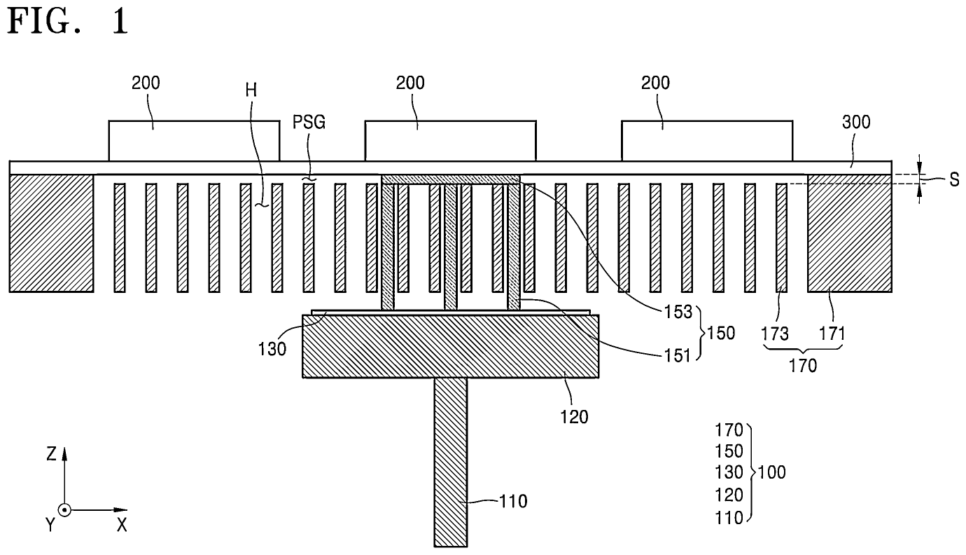

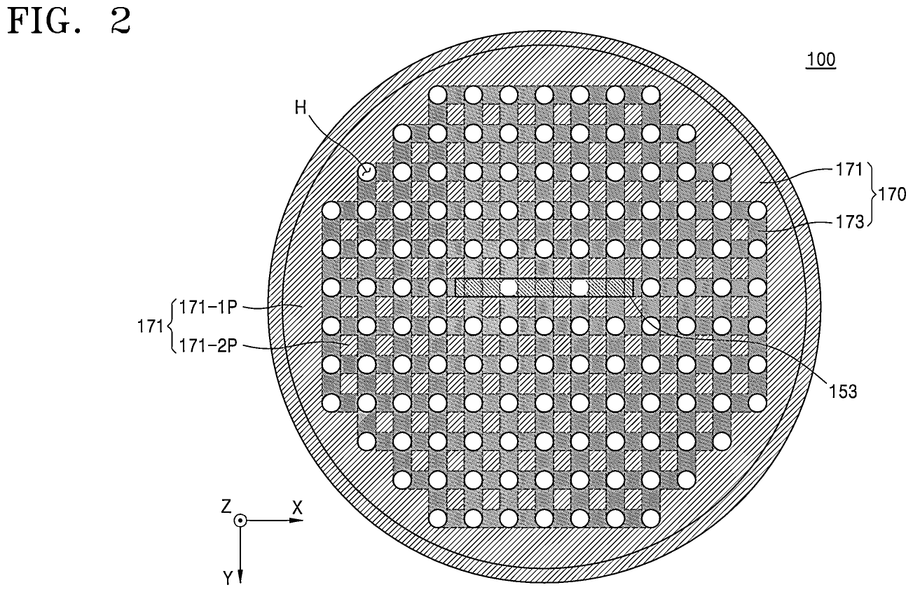

FIG. 1 is a cross-sectional view showing a chip ejector apparatus 100 according to embodiments. FIG. 2 is a plan view showing the chip ejector apparatus 100 according to embodiments.

Referring to FIGS. 1 and 2, the chip ejector apparatus 100 may include a support rod 110, a pin support 120, a holder 170, a pin coupling member 130, and a pressing member 150. The chip ejector apparatus 100 may be disposed below a mount tape 300 to which a chip 200 is attached. According to embodiments, the upper surface and lower surface of the mount tape 300 may be flat. At least one chip 200 may be disposed on the upper surface of the mount tape 300. As used herein, the chip 200 may be understood as a diced individual chip. In some embodiments, at least one chip 200 may be attached to the upper surface of the mount tape 300. The chip 200 with the mount tape 300 may be understood as a diced individual chip obtained after a sawing process is completed.

In the following drawings, an X-axis direction and a Y-axis direction may represent directions parallel to the upper or lower surface of the mount tape 300, and the X-axis direction and the Y-axis direction may be perpendicular to each other. A Z-axis direction may represent a direction perpendicular to the upper or lower surface of the mount tape 300. In other words, the Z-axis direction may be perpendicular to an X-Y plane.

Also, in the following drawings, a first horizontal direction, a second horizontal direction, and a vertical direction may be understood as follows. The first horizontal direction may be understood as the X-axis direction, the second horizontal direction may be understood as the Y-axis direction, and the vertical direction may be understood as the Z-axis direction.

The chip ejector apparatus 100 may be disposed below the mount tape 300. According to embodiments, the mount tape 300 may be supported by the chip ejector apparatus 100. Specifically, the mount tape 300 may be supported by the holder 170. The holder 170 may be located between the chip 200 and the pin support 120. The holder 170 may include a first body 171 and a second body 173. The first body 171 may support the mount tape 300 and the second body 173 may be spaced apart from the mount tape 300 in the vertical direction Z. According to embodiments, the second body 173 may include a plurality of holes H that pass through the second body 173 in the vertical direction Z. The first body 171 may not include a hole. In some embodiments, the first body 171 may contact the mount tape 300, and the second body 173 may be spaced apart from the mount tape 300. In some embodiments, the plurality of holes H may be formed at the second body and extend from an upper surface of the second body 173 and a lower surface thereof. In some embodiments, no hole may be formed at the first body 171. The term “contact,” or “in contact with,” as used herein, refers to a direct connection (i.e., physical touching) unless the context indicates otherwise.

According to embodiments, the upper surface of the first body 171 may be at a higher vertical level than the upper surface of the second body 173. A height difference S in the vertical direction Z may be formed between the upper surface of the first body 171 and the upper surface of the second body 173. The distance from the lower surface of the mount tape 300 to the upper surface of the second body 173 may be substantially equal to the height difference S. In some embodiments, the upper surface of the first body 171 may be higher than the upper surface of the second body 173 relative to the upper surface of the pin support 120. For example, the height difference S may correspond to a shortest distance between the upper surface of the first body and the upper surface of the second body 173. Terms such as “same,” “equal,” “planar,” or “coplanar,” as used herein encompass near identicality including variations that may occur, for example, due to manufacturing processes. The term “substantially” may be used herein to emphasize this meaning, unless the context or other statements indicate otherwise.

Due to the height difference S, the first body 171 may be in contact with the mount tape 300 in the vertical direction Z, but the second body 173 may be spaced apart from the mount tape 300 in the vertical direction Z. For example, a lower surface of the mount tape 300 may be in contact with the upper surface of the first body 171, and the second body 173 may not be in contact with the mount tape 300.

According to embodiments, the second body 173 may have a grid pattern when viewed from above in the vertical direction Z. For example, when the holder 170 is viewed from the above in the vertical direction Z, the first body 171 may be located in an edge region of the holder 170, the second body 173 having a grid pattern may be located in a central region of the holder 170, and the first body 171 may be located between portions of the second body 173. The second body 173 may include passages PSG that connect the plurality of adjacent holes H to each other. In some embodiments, the first body 171 may include a first portion 171-1P located at the edge region of the holder 170, and a second portion 171-2P located between the portions of the second body 173. For example, the first portion 171-1P of the first body 171 may surround the second body 173 and the second portion 171-2P of the first body 171 when viewed from the above in the vertical direction Z. In some embodiments, the first portion 171 may be connected to the second portion 173 when viewed from the above in the vertical direction Z, and the second portion 173 may be disposed in a space between the first portion 171-1P of the first body 171 and the second portion 171-2P thereof. In some embodiments, the passages PGS may correspond to a space between the upper surface of the second body 173 and an imaginary plane at which the upper surface of the first body 171 is located. The imaginary plane of the first body 171 may correspond to a bottom surface of the mount tape 300.

According to embodiments, the second body 173 may be located between the holes H that are closest to each other among the plurality of holes H in the holder 170 in which the plurality of holes H are formed. For example, when a plurality of holes H are formed in the holder 170 as shown in FIG. 2, one hole H among the plurality of holes H may be provided at a location spaced apart from another hole H in at least one of the first horizontal direction X and the second horizontal direction Y. Accordingly, when one hole H is referred to as a first hole and another hole H is referred to as a second hole, the second body 173 may be located between the first hole and the second hole. In some embodiments, the second body 173 may include a plurality of first patterns extending in the first horizontal direction X and spaced apart from each other in the second horizontal direction Y and a plurality of second patterns extending in the second horizontal direction Y and spaced apart from each other in the first horizontal direction X. The plurality of first patterns and the plurality of second patterns are arranged to form a grid pattern when viewed in the vertical direction. The plurality of holes H may be disposed at a plurality of cross regions among the plurality of first patterns and the plurality of second patterns.

As described below, a horizontal bar 153 is disposed on the upper surface of the second body 173, the second body 173 is located only between the plurality of holes H, the height difference S in the vertical direction Z is formed between the second body 173 and the first body 171, and the thickness of the horizontal bar 153 in the vertical direction Z is substantially equal to the height difference S. Accordingly, the mount tape 300 may be placed in a flat state on the holder 170.

The pin support 120 may be disposed below the holder 170. The pin support 120 may be configured to support a vertical pin 151. The upper surface of the pin support 120 may have a flat shape (i.e., a flat surface). According to embodiments, the pin support 120 may have a rectangular parallelepiped shape.

The support rod 110 may be coupled to the lower surface of the pin support 120. The support rod 110 may support the pin support 120 and be configured to drive the pin support 120 in the vertical direction Z. As the support rod 110 is driven in the vertical direction Z, the pin support 120 coupled to the support rod 110 may also be driven in the vertical direction Z. At least one vertical pin 151 and the horizontal bar 153 may be disposed on the upper surface of the pin support 120, and the at least one vertical pin 151 and the horizontal bar 153 may be driven in the vertical direction Z along with the pin support 120 driven by the support rod 110, which is described below. For example, the support rod 110 may be configured to raise or lower the pin support 120, the vertical pin 151, and the horizontal bar 153 in the vertical direction Z.

The pressing member 150 may be disposed on the upper surface of the pin support 120. The pressing member 150 may be configured to press the lower surface of the mount tape 300. The pressing member 150 may push the lower surface of the mount tape 300 upward in the vertical direction Z so as to separate the chip 200 from the mount tape 300. The pressing member 150 may include the vertical pin 151 and the horizontal bar 153. The vertical pin 151 may be disposed on the upper surface of the pin support 120. The vertical pin 151 may extend lengthwise in the vertical direction Z. According to embodiments, a plurality of vertical pins 151 may be provided. The plurality of vertical pins 151 may be spaced apart from each other in the horizontal direction by a certain distance. In some embodiment, the lengthwise direction of the vertical pin 151 may be parallel to the vertical direction.

The vertical pin 151 may be inserted into the hole H of the holder 170. According to embodiments, the cross-sectional footprint of the vertical pin 151 on the X-Y plane may be smaller than the area of the hole H. The length of the vertical pin 151 in the vertical direction Z may be greater than the length of the second body 173 in the vertical direction Z.

The vertical pin 151 may be fixed on the upper surface of the pin support 120 by the pin coupling member 130. The pin coupling member 130 may be configured to couple with the vertical pin 151 or separate the vertical pin 151. For example, the vertical pin 151 may be replaced with another vertical pin 151 by the pin coupling member 130, or the vertical pin 151 may be moved to another position by the pin coupling member 130. The vertical pin 151 may be disposed at any position on the upper surface of the pin support 120 by the pin coupling member 130. The pin coupling member 130 may be disposed on the upper surface of the pin support 120. In some embodiments, the pin coupling member 130 may detachably accommodate the vertical pin 151. This detachable accommodation of the vertical pin 151 may allow for replacing the vertical pin with another one or shifting its position.

In some embodiments, the number of vertical pins 151 may be three. The three vertical pins 151 may be spaced apart from each other in the first horizontal direction X. The three vertical pins 151 may be respectively inserted into and placed in the holes H of the holder 170. At least one hole H, into which the vertical pin 151 is not inserted, may be located between the vertical pins 151. For example, in FIG. 2, the horizontal bar 153 disposed on the second body 173 may overlap, in the vertical direction Z, five holes H formed in the holder 170. Here, when the five holes H are defined as a first hole, a second hole, a third hole, a fourth hole, and a fifth hole from the left side, the three vertical pins 151 may be respectively inserted into the first hole, the third hole, and the fifth hole one by one, and no vertical pins may be inserted into the second hole and the fourth hole. However, the number and locations of the vertical pins 151 are not limited thereto. The number of vertical pins 151 may be one, two, or four or more, and the vertical pin 151 may also be inserted into any of the holes H formed in the holder 170. According to embodiments, the length of the horizontal bar 153 in the first horizontal direction X may be substantially equal to or less than the length of the chip 200 in the first horizontal direction X. In some embodiments, the example five holes may be aligned along a straight line extend along a lengthwise direction of the horizontal bar 153, for example, the first horizontal direction X direction.

The horizontal bar 153 may be coupled to the upper surface of the vertical pin 151. The horizontal bar 153 may have a shape extending in the first horizontal direction X. The horizontal bar 153 may be supported by at least one vertical pin 151. The horizontal bar 153 may be configured to be coupled to and separated from an upper end of the vertical pin 151 or may be formed integrally with an upper end of the vertical pin 151. In some embodiments, a lower end of the vertical pin 151 may be detachably connected to the pin coupling member 130. In some embodiment, the pin coupling member 130 may include a plurality of recesses, and the lower end of the vertical pin 151 fit into one of the plurality of recesses. Each of the recesses may be dimensioned to detachably accommodate the lower end of the vertical pin 151. In some embodiments, the lower end of the vertical pin 151 may be a threaded cylindrical rod and the pin coupling member 130 may include a threaded recess or a threaded hole so that the vertical pin 151 is tightened onto the pin coupling member 130.

In some embodiments, the horizontal bar 153 may be in contact with the upper surface of the second body 173. However, when the support rod 110 is driven upward in the vertical direction Z, the horizontal bar 153 may be spaced apart from the upper surface of the second body 173 in the vertical direction Z.

The horizontal bar 153 may contact the mount tape 300 in the vertical direction Z. Specifically, the upper surface of the horizontal bar 153 may contact the mount tape 300. The upper surface of the horizontal bar 153 may be coplanar with the upper surface of the first body 171. That is, the upper surface of the horizontal bar 153 may be at the same vertical level as the upper surface of the first body 171.

The thickness of the horizontal bar 153 in the vertical direction Z may be substantially equal to the height difference S in the vertical direction Z between the first body 171 and the second body 173.

In some embodiments, when the horizontal bar 153 is supported by a plurality of vertical pins 151, the side surface of the horizontal bar 153 may be coplanar with the side surface of the vertical pin 151 that is located on the outside among the plurality of vertical pins 151. In some embodiments, the opposite side surfaces, in the first horizontal direction X, of the horizontal bar 153 may be coplanar with outer side surfaces of the outermost vertical pins 151 among the vertical pins 151 under the horizontal bar 153. For example, FIG. 1 shows three vertical pins 151 under the horizontal bar 153, and the leftmost vertical pin and the rightmost vertical pin correspond to the outermost vertical pins 151. The left side surface of the horizontal bar 153 may be coplanar with an outer side surface of the leftmost vertical pin, and the right side surface of the horizontal bar 153 may be coplanar with an outer side surface of the rightmost vertical pin.

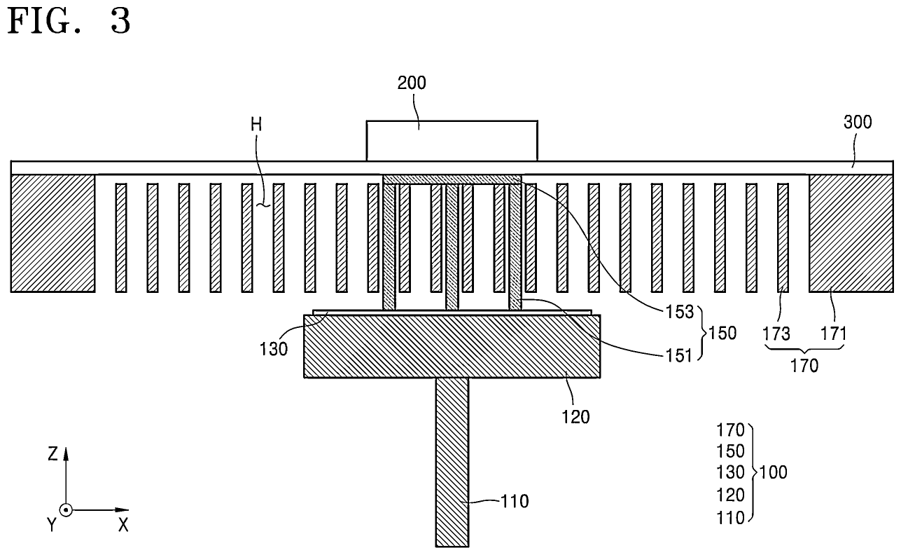

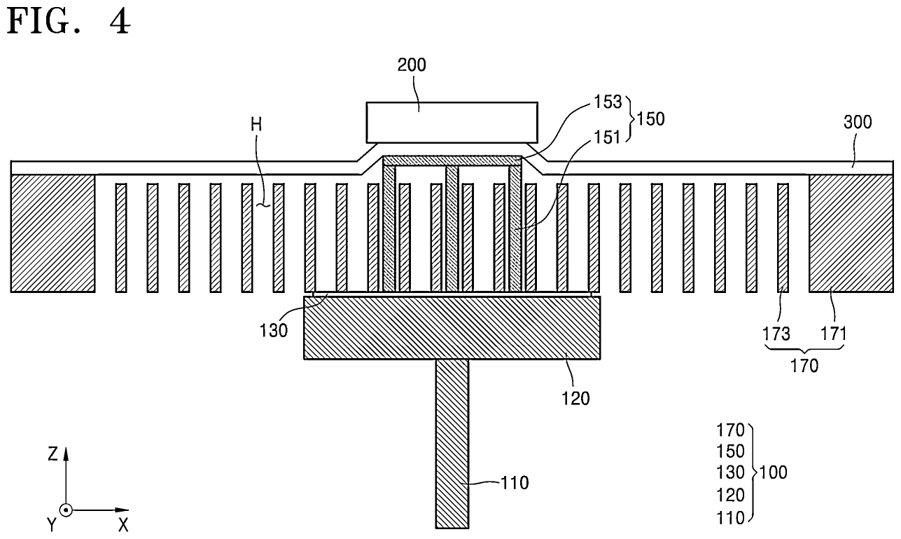

FIGS. 3 and 4 are cross-sectional views showing an operation of a chip ejector apparatus 100 according to embodiments. Hereinafter, repeated descriptions as those given with reference to FIGS. 1 and 2 are omitted, and the description focuses on the differences.

Referring to FIGS. 3 and 4, the chip ejector apparatus 100 may include a support rod 110, a pin support 120, a holder 170, a pin coupling member 130, and a pressing member 150. The pressing member 150 may include a vertical pin 151 and a horizontal bar 153. A mount tape 300, on which a chip 200 is attached, may be disposed on the chip ejector apparatus 100. The mount tape 300 with the chip 200 attached on the upper surface thereof may be supported by the chip ejector apparatus 100.

The support rod 110 may move the pin support 120, the vertical pin 151, and the horizontal bar 153 in the vertical direction Z. Before the support rod 110 is driven upwardly in the vertical direction Z, the chip ejector apparatus 100 may be in a state as shown in FIG. 3. That is, a plurality of vertical pins 151 may be respectively inserted into holes H of the holder 170, and the horizontal bar 153 coupled to the upper surfaces of the vertical pins 151 may be disposed on the upper surface of a second body 173. The pin support 120 and the holder 170 may be spaced apart from each other in the vertical direction Z. Since the lower surface of the horizontal bar 153 is in contact with the upper surface of the second body 173, the upper surface of the horizontal bar 153 may be at the same vertical level as the upper surface of the first body 171. Also, the mount tape 300 may be supported by the first body 171 and the horizontal bar 153. Specifically, the lower surface of the mount tape 300 may be in contact with the upper surface of the first body 171 and the upper surface of the horizontal bar 153.

As the upper surface of the horizontal bar 153 and the upper surface of the first body 171 are at the same vertical level, the mount tape 300 on the upper surface of the horizontal bar 153 and the upper surface of the first body 171 may be placed in a flat state. Due to the height difference S in the vertical direction Z formed between the first body 171 and the second body 173, the mount tape 300 that is disposed on the upper surface of the second body 173 may be placed in a flat state on the holder 170.

Here, when the support rod 110 is driven upward in the vertical direction Z, the state in FIG. 3 may change to the state shown in FIG. 4. The pin support 120, the vertical pin 151, and the horizontal bar 153 are moved upward in the vertical direction Z due to the movement of the support rod 110, and the horizontal bar 153 may press the lower surface of the mount tape 300 in the vertical direction Z. Due to the pressing, a portion of the mount tape 300, which is in contact with the horizontal bar 153, may be pushed upward in the vertical direction Z. On the other hand, the remaining portion of the mount tape 300, which is not in contact with the horizontal bar 153, may maintain the vertical level as shown in FIG. 3. As the portion of the mount tape 300 in contact with the horizontal bar 153 is pushed upward in the vertical direction Z, the chip 200 on the upper surface of the mount tape 300 may be detached from the mount tape 300. In some embodiments, the horizontal bar 153 may evenly distribute the force delivered by the vertical pin 152 moving upward in the vertical direction Z, thereby preventing the chip 200 from cracking during detachment.

According to the related art, the vertical pin 151 contacts the lower surface of the mount tape 300 and move a portion of the mount tape 300 upward in the vertical direction Z. Here, since an area of the lower surface of the mount tape 300, which is in contact with the vertical pin 151, is small, high pressure may be applied only to the portion of the lower surface of the mount tape 300 which is in contact with the vertical pin 151. Cracks occur in the vertical pin 151 and a portion of the lower surface of the mount tape 300 which is in contact with the vertical pin 151. In some cases, the mount tape 300 may be torn, and the chip 200 that is on the torn mount tape 300 may be cracked by the vertical pin 151. When the mount tape 300 is not pushed upward uniformly in the vertical direction Z but pushed upward in an inclined or rotated state, the chip 200 on the upper surface of the mount tape 300 after the detachment from the mount tape 300 may be in an inclined or rotated state.

However, in the chip ejector apparatus 100 according to the present disclosure, the horizontal bar 153 pushes the mount tape 300 upward in the vertical direction Z and may thus uniformly press the lower surface of the mount tape 300. Accordingly, the mount tape 300 is also pushed upward in the vertical direction Z while maintaining a horizontal state without being tilted or rotated. Also, the chip 200 on the upper surface of the mount tape 300 may be detached from the mount tape 300 while maintaining a horizontal state. Accordingly, the occurrence of cracks or pickup failure may be prevented when the chip 200 is separated from the mount tape 300 using a die bonder or the like. Also, the length and size of the horizontal bar 153 may be freely adjusted, and thus, pressure appropriate to the size of the provided chip 200 may be applied to the mount tape 300.

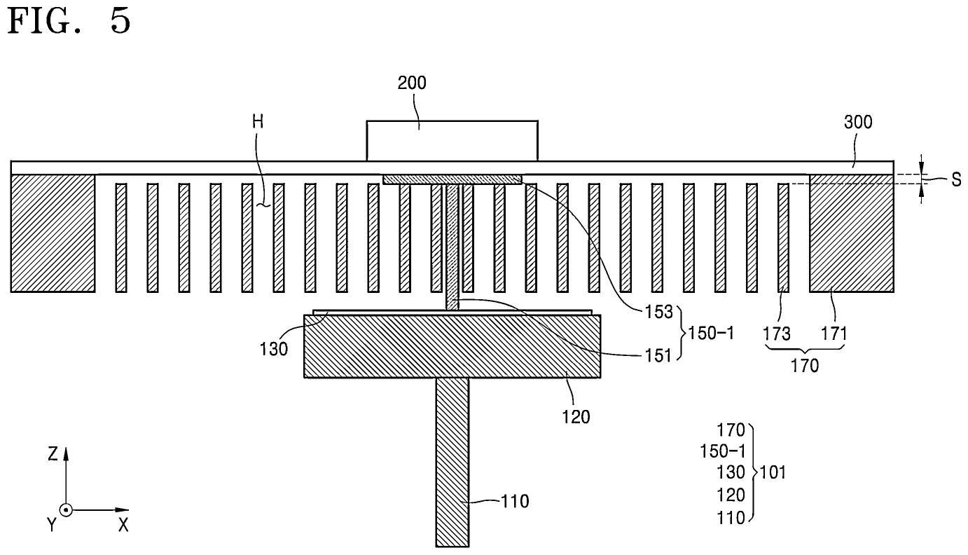

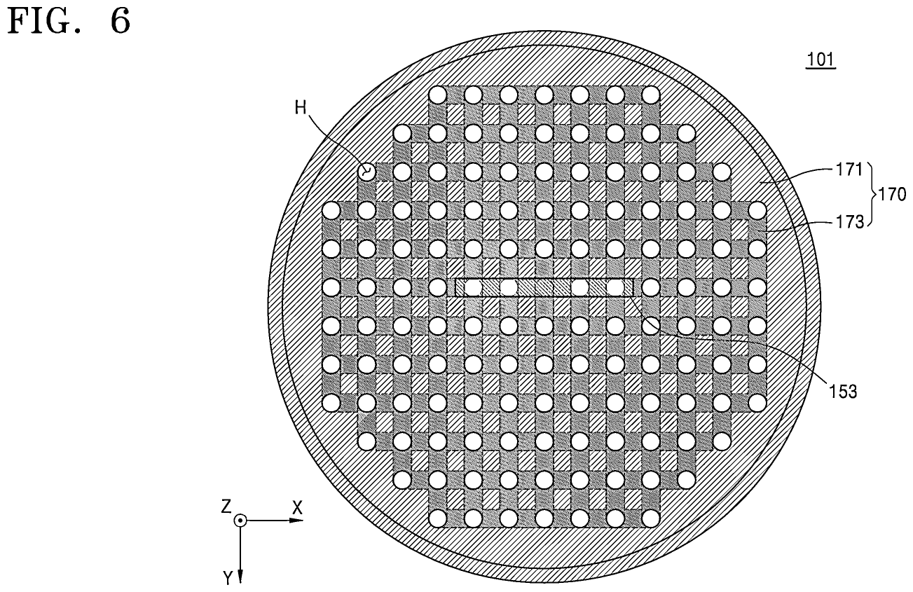

FIG. 5 is a cross-sectional view showing a chip ejector apparatus 101 according to embodiments. FIG. 6 is a plan view showing the chip ejector apparatus 101 according to embodiments. Hereinafter, when describing the chip ejector apparatus 101 with reference to FIG. 5, repeated descriptions of the chip ejector apparatus 100 of FIGS. 1 and 2 are omitted. The description focuses on the differences therebetween.

Referring to FIGS. 5 and 6, the chip ejector apparatus 101 may include a pin support 120, a holder 170, a pin coupling member 130, and a pressing member 150-1. The pressing member 150-1 may include a vertical pin 151 and a horizontal bar 153. A mount tape 300, on which a chip 200 is attached, may be disposed on the chip ejector apparatus 101. The mount tape 300 with the chip 200 attached on the upper surface thereof may be supported by the chip ejector apparatus 101.

According to embodiments, the pressing member 150-1 may include one vertical pin 151 (i.e., a single vertical pin) and the horizontal bar 153. The vertical pin 151 may be located at the center of the pin support 120 and fixed on the upper surface of the pin support 120 by the pin coupling member 130. The horizontal bar 153 may be coupled to the upper surface of the vertical pin 151. The vertical pin 151 may be coupled to the central portion of the lower surface of the horizontal bar 153. According to embodiments, the horizontal bar 153 may overlap five holes H in a vertical direction Z as shown in FIG. 6. When the five holes H are defined as a first hole, second hole, third hole, fourth hole, and fifth hole in this order from the left side, the vertical pin 151 may be inserted into the third hole. However, the number of holes H overlapping the horizontal bar 153 is not limited thereto, and the hole into which the vertical pin 151 is inserted is also not limited to the third hole. A side surface of the horizontal bar 153 in the first horizontal direction X may not be coplanar with a side surface of the vertical pin 151.

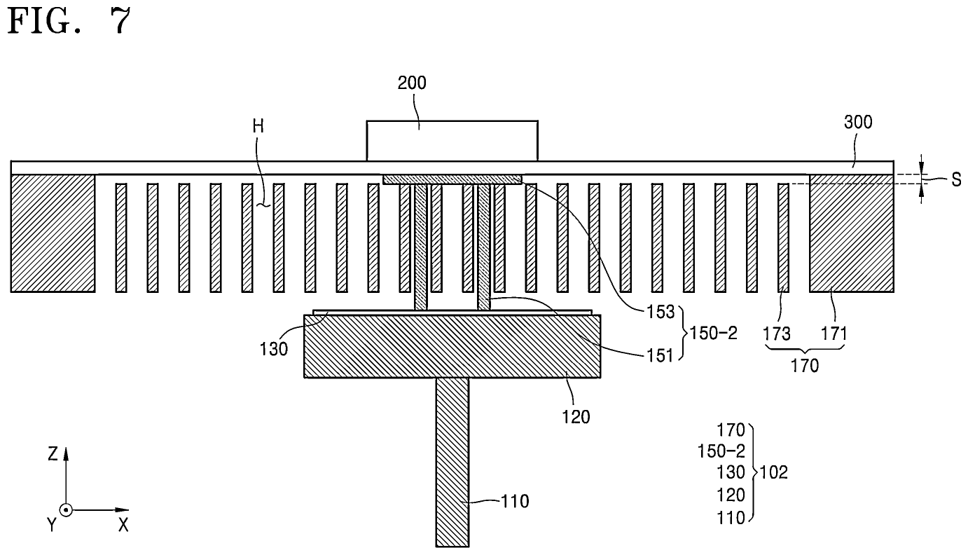

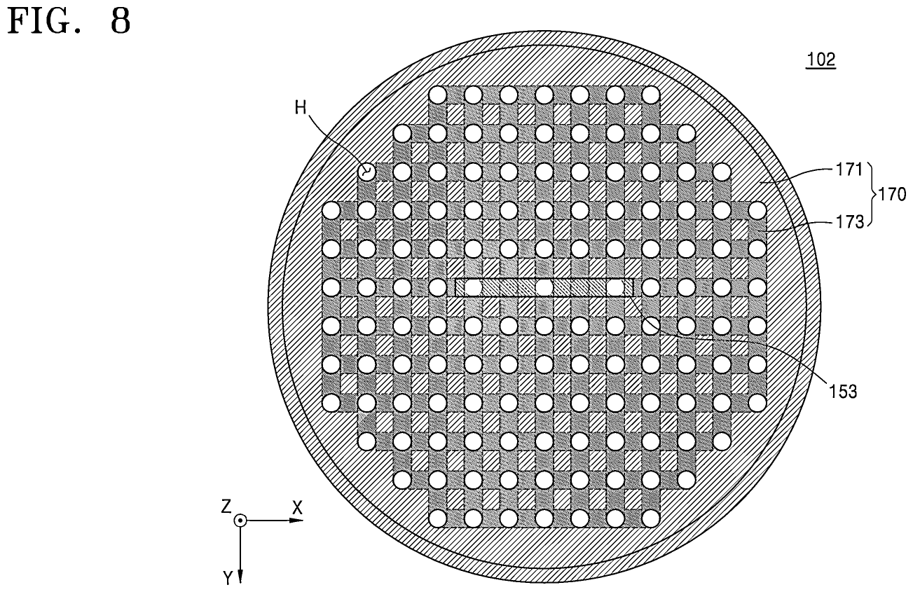

FIG. 7 is a cross-sectional view showing a chip ejector apparatus 102 according to embodiments. FIG. 8 is a plan view showing the chip ejector apparatus 102 according to embodiments. Hereinafter, when describing the chip ejector apparatus 102 with reference to FIGS. 7 and 8, repeated descriptions of the chip ejector apparatus 101 of FIGS. 5 and 6 are omitted. The description focuses on the differences therebetween.

Referring to FIGS. 7 and 8, the chip ejector apparatus 102 may include a pin support 120, a holder 170, a pin coupling member 130, and a pressing member 150-2. The pressing member 150-2 may include a vertical pin 151 and a horizontal bar 153. A mount tape 300, on which a chip 200 is attached, may be disposed on the chip ejector apparatus 102. The mount tape 300 with the chip 200 attached on the upper surface thereof may be supported by the chip ejector apparatus 102.

According to embodiments, the pressing member 150-2 may include two vertical pins 151 and one horizontal bar 153. The two vertical pins 151 may be arranged on the pin support 120 and spaced apart from each other in a first horizontal direction X. The two vertical pins 151 may be fixed on the upper surface of the pin support 120 by the pin coupling member 130. The horizontal bar 153 may be coupled to the upper surfaces of the vertical pins 151. According to embodiments, the horizontal bar 153 may overlap five holes H in a vertical direction Z as shown in FIG. 8. When the five holes H are defined as a first hole, a second hole, a third hole, a fourth hole, and a fifth hole in this order from the left side, the vertical pins 151 may be respectively inserted into the second hole and the fourth hole one by one. However, the number of holes H overlapping the horizontal bar 153 is not limited thereto, and the holes into which the vertical pins 151 are inserted are also not limited to the second hole and fourth hole. A side surface of the horizontal bar 153 in the first horizontal direction X may not be coplanar with side surfaces of the vertical pins 151. For example, opposite side surfaces of the horizontal bar 153 in the first horizontal direction may be outwardly distant from an outer side surface of a first vertical pin and an outer side surface of a second vertical pin, respectively. When two or more vertical pins are connected to the horizontal bar 153, one of the first vertical pin and the second vertical pin corresponds to a leftmost vertical pin among the two or more vertical pins and the other corresponds to a rightmost vertical pin among the two or more vertical pins.

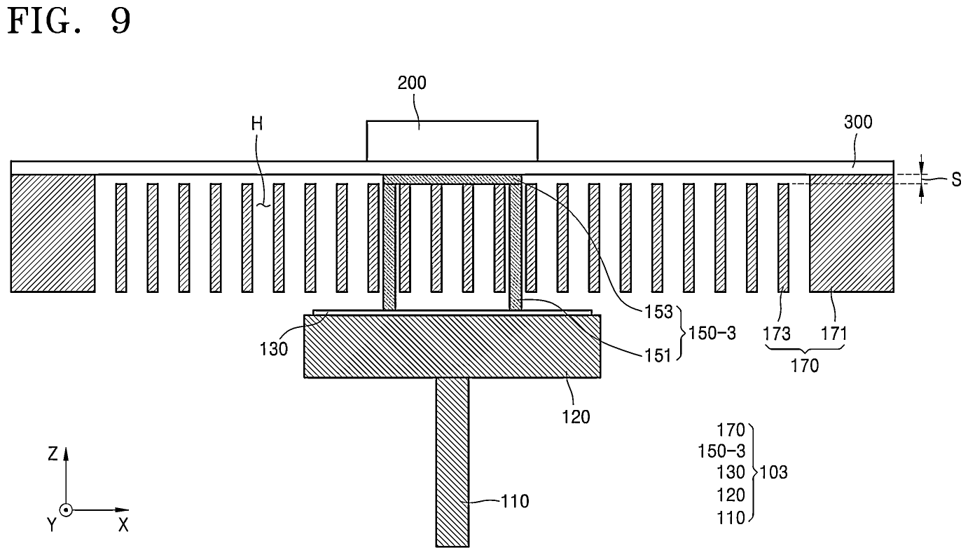

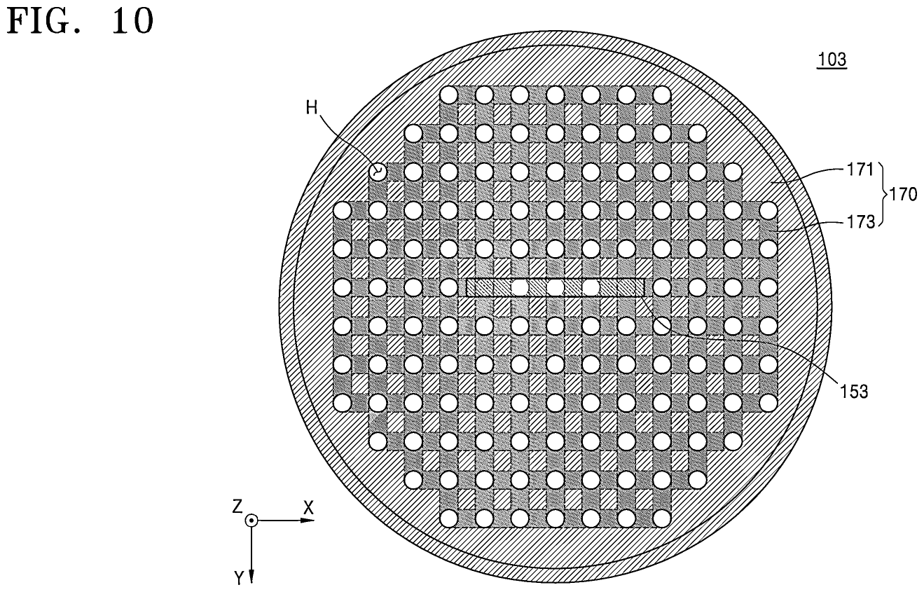

FIG. 9 is a cross-sectional view showing a chip ejector apparatus 103 according to embodiments. FIG. 10 is a plan view showing the chip ejector apparatus 103 according to embodiments. Hereinafter, when describing the chip ejector apparatus 103 with reference to FIGS. 9 and 10, repeated descriptions of the chip ejector apparatus 102 of FIGS. 7 and 8 are omitted. The description focuses on the differences therebetween.

Referring to FIGS. 9 and 10, the chip ejector apparatus 103 may include a pin support 120, a holder 170, a pin coupling member 130, and a pressing member 150-3. The pressing member 150-3 may include a vertical pin 151 and a horizontal bar 153. A mount tape 300, on which a chip 200 is attached, may be disposed on the chip ejector apparatus 103. The mount tape 300 with the chip 200 attached on the upper surface thereof may be supported by the chip ejector apparatus 103.

According to embodiments, the pressing member 150-3 may include two vertical pins 151 and one horizontal bar 153. The two vertical pins 151 may be arranged on the pin support 120 and spaced apart from each other in a first horizontal direction X. The two vertical pins 151 may be fixed on the upper surface of the pin support 120 by the pin coupling member 130. The horizontal bar 153 may be coupled to the upper surfaces of the vertical pins 151. According to embodiments, the horizontal bar 153 may overlap five holes H in a vertical direction Z as shown in FIG. 10. When the five holes H are defined as a first hole, a second hole, a third hole, a fourth hole, and a fifth hole in this order from the left side, the vertical pins 151 may be respectively inserted into the first hole and fifth hole one by one. However, the number of holes H overlapping the horizontal bar 153 is not limited thereto, and the holes into which the vertical pins 151 are inserted are also not limited to the first hole and fifth hole. According to embodiments, opposite side surfaces of the horizontal bar 153 in the first horizontal direction X may be respectively coplanar with corresponding side surfaces of the two vertical pins 151.

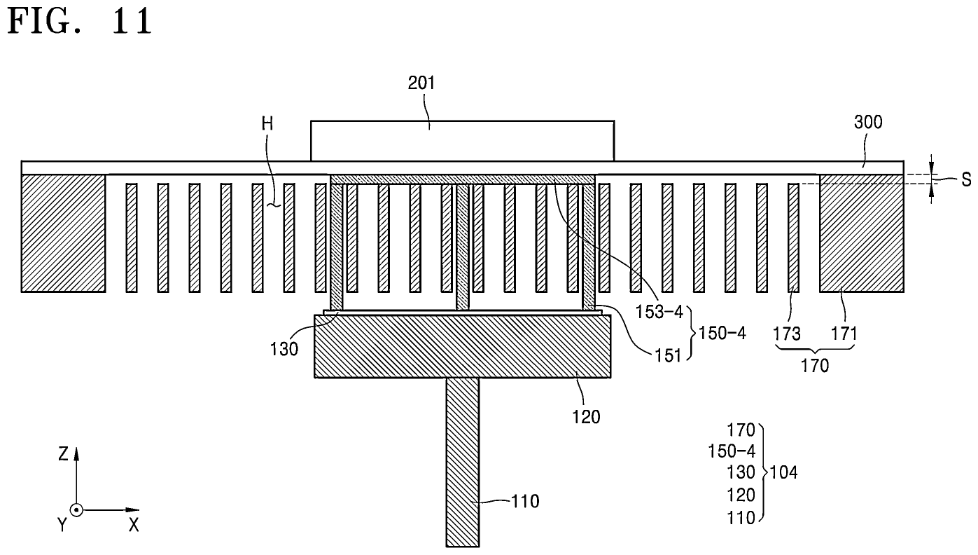

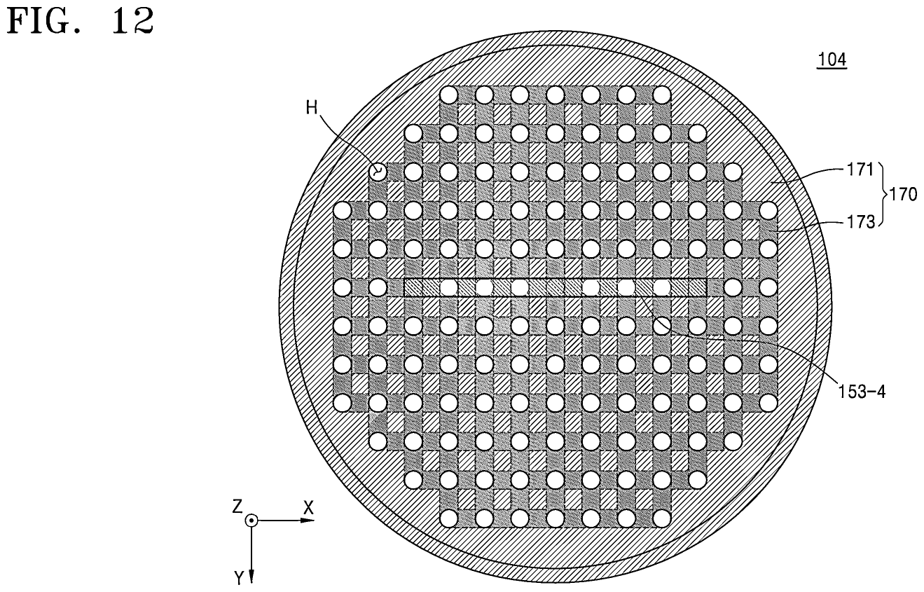

FIG. 11 is a cross-sectional view showing a chip ejector apparatus 104 according to embodiments. FIG. 12 is a plan view showing the chip ejector apparatus 104 according to embodiments. Hereinafter, when describing the chip ejector apparatus 104 with reference to FIGS. 11 and 12, repeated descriptions of the chip ejector apparatus 100 of FIGS. 1 and 2 are omitted. The description focuses on the differences therebetween.

Referring to FIGS. 11 and 12, the chip ejector apparatus 104 may include a pin support 120, a holder 170, a pin coupling member 130, and a pressing member 150-4. The pressing member 150-4 may include a vertical pin 151 and a horizontal bar 153-4. A mount tape 300, on which a chip 201 is attached, may be disposed on the chip ejector apparatus 104. The mount tape 300 with the chip 201 attached on the upper surface thereof may be supported by the chip ejector apparatus 104.

The chip 201 may overlap, in a vertical direction Z, holes H formed in the holder 170. According to embodiments, the chip 201 may overlap nine holes H in the vertical direction Z. The chip 201 may be different from the chip 200 in other embodiments in size. For example, the chip 201 may be greater than the chip 200 in size (e.g., a length in the first horizontal direction X).

According to embodiments, the pressing member 150-4 may include three vertical pins 151 and one horizontal bar 153-4. In some embodiment, the horizontal bar 153-4 may be greater than the horizontal bar 153 of FIG. 1 in size (e.g., a length in the first horizontal direction X). The three vertical pins 151 may be arranged on the pin support 120 and spaced apart from each other in a first horizontal direction X. The three vertical pins 151 may be fixed on the upper surface of the pin support 120 by the pin coupling member 130. The horizontal bar 153-4 may be coupled to the upper surfaces of the vertical pins 151. According to embodiments, the horizontal bar 153-4 may overlap the nine holes H in a vertical direction Z as shown in FIG. 12. When the nine holes H are defined as a first hole, a second hole, a third hole, a fourth hole, a fifth hole, a sixth hole, a seventh hole, an eighth hole, and a ninth hole in this order from the left side, the vertical pins 151 may be respectively inserted into the first hole, the fifth hole, and the ninth hole one by one. However, the number of holes H overlapping the horizontal bar 153-4 is not limited thereto, and the holes into which the vertical pins 151 are inserted are also not limited to the first hole, fifth hole, and ninth hole. According to embodiments, opposite side surfaces of the horizontal bar 153-4 in the first horizontal direction X may be respectively coplanar with corresponding side surfaces of the vertical pins 151. In some embodiments, the opposite side surfaces, in the first horizontal direction X, of the horizontal bar 153-4 may be coplanar with outer side surfaces of the outermost vertical pins 151 among the three vertical pins 151 under the horizontal bar 153. For example, the leftmost vertical pin and the rightmost vertical pin correspond to the outermost vertical pins 151, and the left side surface of the horizontal bar 153-4 may be coplanar with an outer side surface of the leftmost vertical pin, and the right side surface of the horizontal bar 153-4 may be coplanar with an outer side surface of the rightmost vertical pin.

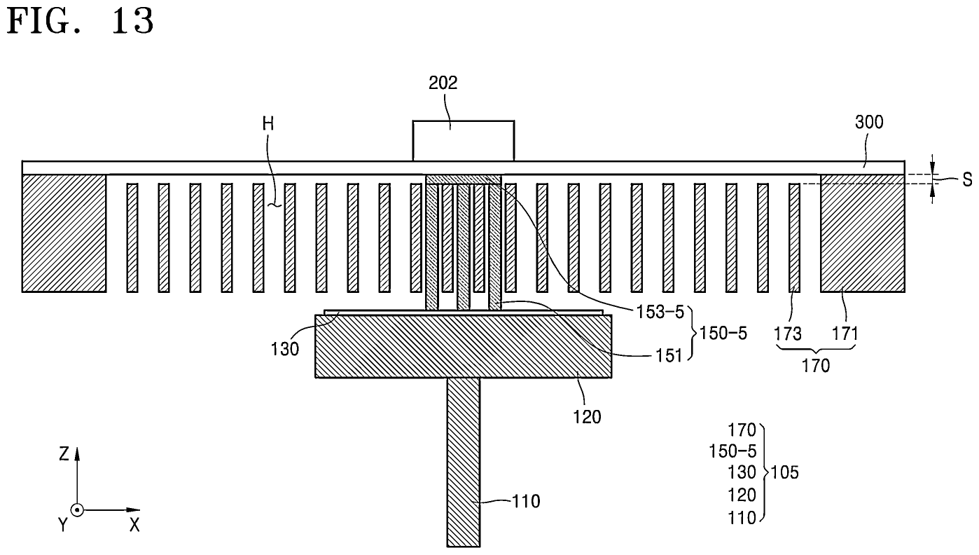

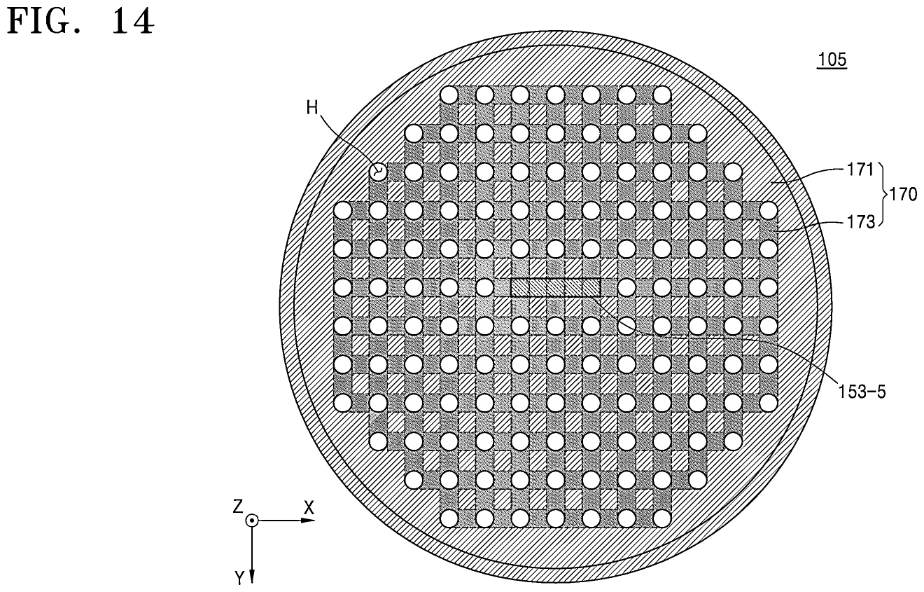

FIG. 13 is a cross-sectional view showing a chip ejector apparatus 105 according to embodiments. FIG. 14 is a plan view showing the chip ejector apparatus 105 according to embodiments. Hereinafter, when describing the chip ejector apparatus 105 with reference to FIGS. 13 and 14, repeated descriptions of the chip ejector apparatus 100 of FIGS. 1 and 2 are omitted. The description focuses on the differences therebetween.

Referring to FIGS. 13 and 14, the chip ejector apparatus 105 may include a pin support 120, a holder 170, a pin coupling member 130, and a pressing member 150-5. The pressing member 150-5 may include a vertical pin 151 and a horizontal bar 153-5. A mount tape 300, on which a chip 202 is attached, may be disposed on the chip ejector apparatus 105. The mount tape 300 with the chip 202 attached on the upper surface thereof may be supported by the chip ejector apparatus 105.

The chip 202 may overlap, in a vertical direction Z, holes H formed in the holder 170. According to embodiments, the chip 202 may overlap three holes H in the vertical direction Z. In some embodiments, the chip 202 may be smaller than the chip 200 of FIG. 1 in size (e.g., a length in the first horizontal direction X).

According to embodiments, the pressing member 150-5 may include three vertical pins 151 and one horizontal bar 153-5. The three vertical pins 151 may be arranged on the pin support 120 and spaced apart from each other in a first horizontal direction X. The three vertical pins 151 may be fixed on the upper surface of the pin support 120 by the pin coupling member 130. The horizontal bar 153-5 may be coupled to the upper surfaces of the vertical pins 151. According to embodiments, the horizontal bar 153-5 may overlap the three holes H in the vertical direction Z as shown in FIG. 14. When the three holes H are defined as a first hole, a second hole, and a third hole in this order from the left side, the three vertical pins 151 may be respectively inserted into the first hole, second hole, and third hole one by one. That is, empty holes H, into which the vertical pins 151 are not inserted, do not exist in spaces between the vertical pins 151 in the first horizontal direction X. In some embodiments, the three holes H may be consecutively arranged in the first horizontal direction X, and the three vertical pins 151 may be inserted into the three holes H, respectively. For example, no intervening hole may be present between two adjacent holes of the three holes that are consecutively arranged in the first horizontal direction X and in which the three vertical pins 151 are inserted. However, the number of holes H overlapping the horizontal bar 153-5 is not limited thereto. According to embodiments, opposite side surfaces of the horizontal bar 153-5 in the first horizontal direction X may be respectively coplanar with corresponding side surfaces of the vertical pins 151. In some embodiments, the opposite side surfaces, in the first horizontal direction X, of the horizontal bar 153-5 may be coplanar with outer side surfaces of the outermost vertical pins 151 among the three vertical pins 151 under the horizontal bar 153. No hole may exist between two adjacent verticals of the three vertical pins 151. For example, the leftmost vertical pin and the rightmost vertical pin correspond to the outermost vertical pins 151, and the left side surface of the horizontal bar 153-5 may be coplanar with an outer side surface of the leftmost vertical pin, and the right side surface of the horizontal bar 153-5 may be coplanar with an outer side surface of the rightmost vertical pin.

While the present disclosure has been particularly shown and described with reference to embodiments thereof, it will be understood that various changes in form and details may be made therein without departing from the spirit and scope of the following claims.

What is claimed is:

1. A chip ejector apparatus comprising:
a holder located below a chip and defining a plurality of holes extending in a vertical direction;
a pin support located below the holder, wherein an upper surface of the pin support is adjacent to the holder;
a support rod coupled to a lower surface of the pin support and configured to be driven in the vertical direction;
a first vertical pin extending lengthwise in the vertical direction and disposed on the upper surface of the pin support, wherein the first vertical pin is inserted into a first hole of the plurality of holes, and wherein a lengthwise direction of the first vertical pin is parallel to the vertical direction; and
a horizontal bar extending lengthwise in a first horizontal direction and coupled to an upper surface of the first vertical pin, wherein a lengthwise direction of the horizontal bar is parallel to the first horizontal direction.

2. The chip ejector apparatus of claim 1,
wherein the holder has a first body and a second body,
wherein the plurality of holes extends from an upper surface of the second body to a lower surface of the second body in the vertical direction, and
wherein an upper surface of the first body is higher than the upper surface of the second body relative to the upper surface of the pin support in the vertical direction.

3. The chip ejector apparatus of claim 2,
wherein a thickness of the horizontal bar in the vertical direction is substantially equal to a height difference between the upper surface of the first body and the upper surface of the second body in the vertical direction.

4. The chip ejector apparatus of claim 2,
wherein the second body includes a plurality of first patterns extending in the first horizontal direction and a plurality of second patterns extending in a second horizontal direction,
wherein the plurality of first patterns and the plurality of second patterns are arranged to form a grid pattern when viewed in the vertical direction, and
wherein the plurality of holes are disposed at a plurality of cross regions among the plurality of first patterns and the plurality of second patterns.

5. The chip ejector apparatus of claim 1, further comprising:
a second vertical pin extending in the vertical direction and disposed on the upper surface of the pin support,
wherein the second vertical pin is inserted into a second hole, different from the first hole, of the plurality of holes, and
wherein the second vertical pin is coupled to the horizontal bar.

6. The chip ejector apparatus of claim 5,
wherein at least two vertical pins are coupled to the horizontal bar, and
wherein the at least two vertical pins include the first vertical pin and the second vertical pin that are spaced apart from each other in the first horizontal direction.

7. The chip ejector apparatus of claim 6,
wherein opposite side surfaces of the horizontal bar in the first horizontal direction are outwardly distant from an outer side surface of the first vertical pin and an outer side surface of the second vertical pin, respectively.

8. The chip ejector apparatus of claim 1,
wherein a length of the horizontal bar in the first horizontal direction is substantially equal to or less than a length of the chip in the first horizontal direction.

9. The chip ejector apparatus of claim 5, further comprising:
a third vertical pin extending in the vertical direction and disposed on the upper surface of the pin support,
wherein the third vertical pin is inserted into a third hole, different from the first hole and the second hole, of the plurality of holes,
wherein the horizontal bar is coupled to the third vertical pin, and
wherein the first hole, the second hole, and the third hole are consecutively arranged in the first horizontal direction.

10. The chip ejector apparatus of claim 5,
wherein a third hole is disposed in a space between the first vertical pin and the second vertical pin,
wherein no vertical pin is inserted into the third hole, and
wherein the first hole, the second hole, and the third hole are arranged in the first horizontal direction.

11. The chip ejector apparatus of claim 1,
wherein the holder has a first body and a second body,
wherein the horizontal bar is disposed on an upper surface of the second body, and
wherein an upper surface of the horizontal bar is at substantially a same vertical level as an upper surface of the first body.

12. A chip ejector apparatus comprising:
a holder having a first body and a second body, wherein a plurality of holes extend from an upper surface of the second body to a lower surface of the second body in a vertical direction, and wherein a mount tape that is attached to a chip is disposed on an upper surface of the first body;
a pin support located below the holder;
a support rod coupled to a lower surface of the pin support and configured to be driven in the vertical direction;
a plurality of vertical pins disposed on an upper surface of the pin support, wherein each vertical pin of the plurality of vertical pins extends lengthwise in the vertical direction and is inserted into a corresponding hole among the plurality of holes; and
a horizontal bar extending lengthwise in a first horizontal direction and coupled to an upper surface of each vertical pin of the plurality of vertical pins,
wherein the upper surface of the first body is higher than the upper surface of the second body in the vertical direction relative to the upper surface of the pin support, and
wherein the first horizontal direction is parallel to a lengthwise direction of the horizontal bar and the vertical direction is parallel to a lengthwise direction of each vertical pin of the plurality of vertical pins.

13. The chip ejector apparatus of claim 12,
wherein a thickness of the horizontal bar in the vertical direction is substantially equal to a height difference between the upper surface of the first body and the upper surface of the second body in the vertical direction.

14. The chip ejector apparatus of claim 12,
wherein the second body is located in spaces between the plurality of holes of the holder, and
wherein the plurality of holes are arranged in the first horizontal direction and a second horizontal direction perpendicular to the first horizontal direction.

15. The chip ejector apparatus of claim 12,
wherein a side surface, in the first horizontal direction, of the horizontal bar in the first horizontal direction is coplanar with a side surface, in the first horizontal direction, of a first vertical pin of the plurality of vertical pins.

16. The chip ejector apparatus of claim 12,
wherein a length of the horizontal bar in the first horizontal direction is substantially equal to or less than a length of the chip in the first horizontal direction.

17. The chip ejector apparatus of claim 12,
wherein a pin coupling member is located between the plurality of vertical pins and the pin support, and
wherein the pin coupling member is configured to be detachably coupled to each vertical pin of the plurality of vertical pins.

18. A chip ejector apparatus comprising:
a holder having a first body and a second body, wherein the second body defines a plurality of holes, wherein the plurality of holes extend from an upper surface of the second body to a lower surface of the second body in a vertical direction, and wherein a mount tape that is attached to a chip is disposed on an upper surface of the first body;
a pin support located below the holder;
a support rod coupled to a lower surface of the pin support and configured to be driven in the vertical direction;
a plurality of vertical pins disposed on an upper surface of the pin support, wherein each vertical pin of the plurality of vertical pins extends lengthwise in the vertical direction and is inserted into a corresponding hole among the plurality of holes;
a pin coupling member located between the pin support and the plurality of vertical pins and configured to be detachably coupled to each vertical pin of the plurality of vertical pins; and
a horizontal bar coupled to an upper surface of each vertical pin of the plurality of vertical pins and extending lengthwise in a first horizontal direction,
wherein a length of the horizontal bar in the first horizontal direction is substantially equal to or less than a length of the chip in the first horizontal direction,
wherein a height difference in the vertical direction corresponds to a shortest distance between the upper surface of the first body and the upper surface of the second body, and
wherein a thickness of the horizontal bar in the vertical direction is substantially equal to the height difference between the upper surface of the first body and the upper surface of the second body in the vertical direction.

19. The chip ejector apparatus of claim 18,
wherein at least one hole of the plurality of holes is disposed in a space between two adjacent vertical pins of the plurality of vertical pins, and
wherein the at least one hole and the two adjacent vertical pins are arranged in the first horizontal direction and are disposed under the horizontal bar.

20. The chip ejector apparatus of claim 18,
wherein the plurality of vertical pins are arranged along the horizontal bar in the first horizontal direction and include a leftmost vertical pin and a rightmost vertical pin, and
wherein when viewed in a plan view, opposite side surfaces of the horizontal bar in the first horizontal direction are distant from an outer side surface of the leftmost vertical pin and an outer side surface of the rightmost vertical pin, respectively.
